(19) United States
(12) Patent Application Publication
(10) Pub. No.: US 2024/0105756 A1
(43) Pub. Date: Mar. 28, 2024

(54) FILM FOR TRANSFERRING AN IMAGE SENSOR AND METHOD OF MANUFACTURING AN IMAGE SENSOR PACKAGE USING THE SAME

(71) Applicant: SAMSUNG ELECTRONICS CO., LTD., Suwon-si (KR)

(72) Inventor: Dusik JUNG, Suwon-si (KR)

(73) Assignee: SAMSUNG ELECTRONICS CO., LTD., Suwon-si (KR)

(21) Appl. No.: 18/237,752

(22) Filed: Aug. 24, 2023

(30) Foreign Application Priority Data
Sep. 27, 2022 (KR) 10-2022-0122480

(51) Int. Cl. H01L 27/146

(52) U.S. Cl. CPC H01L 27/14685; H01L 27/14627; H01L 27/14636

(57) ABSTRACT

A film for transferring an image sensor includes: a first surface and a second surface opposite the first surface in a vertical direction; protrusion portions disposed in a horizontal direction on the first surface; and a recess on each of the protrusion portions.

### CROSS-REFERENCE TO RELATED APPLICATION

This application claims priority to Korean Patent Application No. 10-2022-0122480, filed on Sep. 27, 2022, in the Korean Intellectual Property Office (KIPO), the disclosure of which is incorporated by reference herein in its entirety.

### BACKGROUND

### 1. Field

Example embodiments relate to film for transferring an image sensor and a method of manufacturing an image sensor package using the same.

### 2. Description of the Related Art

An image sensor chip includes a microlens, and a film for transferring an image sensor chip. If an adhesion between the microlens and the film is too high, separating the image sensor chip from the film may be difficult.

### SUMMARY

One or more example embodiments provide a film for transferring an image sensor having improved characteristics.

One or more example embodiments provide a method of manufacturing an image sensor package using a film for transferring an image sensor having improved characteristics.

According to an aspect of an example embodiment, a film for transferring an image sensor includes a first surface and a second surface opposite the first surface in a vertical direction; protrusion portions disposed in a horizontal direction on the first surface; and a recess on each of the protrusion portions.

According to an aspect of an example embodiment, a method of manufacturing an image sensor package includes: separating an image sensor chip attached to a first surface of a film for transferring an image sensor from the film, the film being attached to a ring, the film comprising the first surface and a second surface opposite to the first surface in a vertical direction, and the film comprising protrusion portions disposed in a horizontal direction on the first surface of the film; mounting the image sensor chip onto a package substrate; forming an adhesion layer on the image sensor chip; placing a transparent plate onto the adhesion layer; and forming a sealing element on the package substrate and sidewalls of the image sensor chip, the adhesion layer and the transparent plate.

According to an aspect of an example embodiment, a method of manufacturing an image sensor package includes: separating an image sensor chip attached to a first surface of a film for transferring an image sensor from the film, the film being attached to a ring, the film comprising the first surface and a second surface opposite to the first surface in a vertical direction, the film comprising protrusion portions disposed in a horizontal direction on the first surface of the film, and the film comprising a recess on each of the protrusion portions; mounting the image sensor chip onto a package substrate; placing a conductive wire configured to electrically connect the image sensor chip to the package substrate; forming an adhesion layer on the image sensor chip; placing a transparent plate onto the adhesion layer; and forming a sealing element on the package substrate and sidewalls of the image sensor chip, the adhesion layer and the transparent plate.

### BRIEF DESCRIPTION OF DRAWINGS

The above and other aspects and features will be more apparent from the following description of example embodiments, taken in conjunction with the accompanying drawings, in which:

FIG. 1 is a plan view illustrating a film for transferring an image sensor in accordance with example embodiments, FIG. 2 is a cross-sectional view taken along line A-A′ of FIG. 1, and FIG. 3 is an enlarged cross-sectional view of region X of FIG. 2.

FIG. 4 is a plan view illustrating a film for transferring an image sensor, and FIG. 5 is a cross-sectional view taken along line A-A′ of FIG. 3.

FIGS. 6 to 8 are cross-sectional views illustrating a method of manufacturing an image sensor package in accordance with example embodiments.

FIG. 9 is a cross-sectional view illustrating a film for transferring an image sensor in accordance with example embodiments.

### DETAILED DESCRIPTION

Example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

A direction substantially parallel to a reference substrate may be referred to as a horizontal direction, and a direction substantially perpendicular to a surface of the reference substrate may be referred to as a vertical direction. In the specifications, up vs. down, on and over vs. beneath and under, upper surface vs. lower surface, and upper portion vs. lower portion are relative conceptions so as to describe opposite sides in the vertical direction, and each wording may have opposite meanings according to the specific parts to be explained in the specifications.

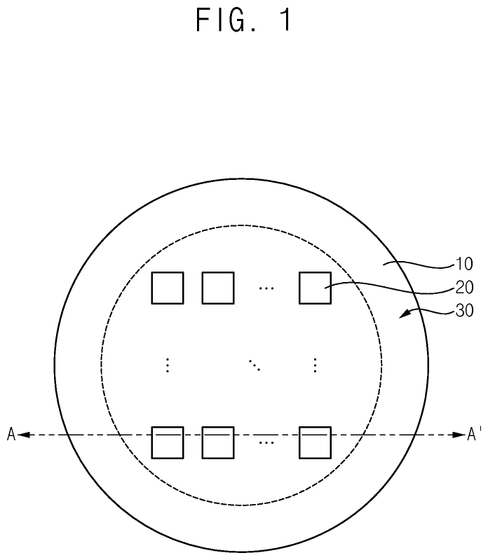

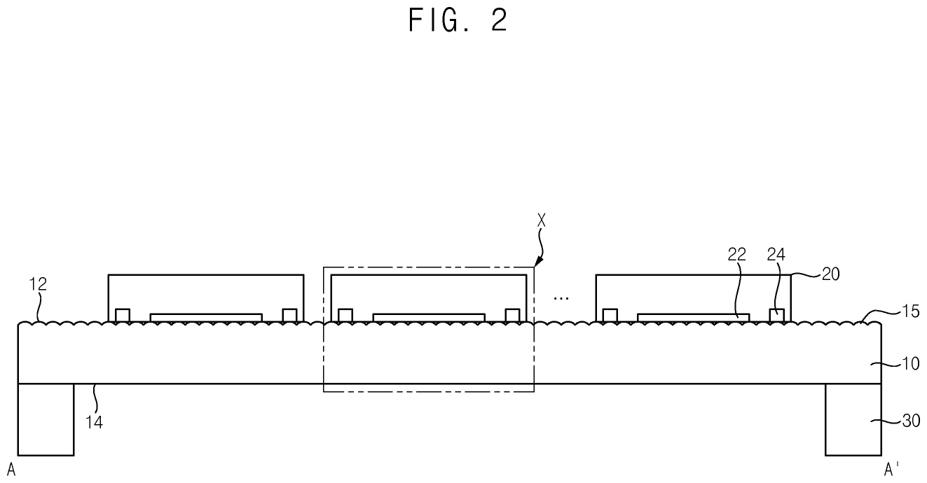

FIG. 1 is a plan view illustrating a film for transferring an image sensor in accordance with example embodiments, FIG. 2 is a cross-sectional view taken along line A-A′ of FIG. 1, and FIG. 3 is an enlarged cross-sectional view of region X of FIG. 2.

Referring to FIGS. 1 to 3, a film 10 for transferring an image sensor may be formed on a ring 30, and an image sensor chip 20 may be disposed on the film 10.

In example embodiments, the image sensor chip 20 may include a CMOS image sensor (CIS).

A plurality of image sensor chips 20 may be spaced apart from each other in the horizontal direction on the film 10. Each of the image sensor chips 20 may include a first surface 27 and a second surface 29 opposite to the first surface 27 in the vertical direction, and may include a lens structure 22 and a conductive pad 24 adjacent to the first surface 27.

In example embodiments, the lens structure 22 may include a plurality of nano prisms 21 disposed in the horizontal direction. The conductive pad 24 may be disposed at an edge portion of each of the image sensor chips 20 in a plan view, and the lens structure 22 may be disposed at a central portion of each of the image sensor chips 20 in a plan view.

The lens structure 22 including the nano prisms 21 may include a first surface 23 and a second surface 25 opposite to the first surface 23 in the vertical direction, and the first surface 23 of the lens structure 22 may be a portion of the first surface 27 of each of the image sensor chips 20. In example embodiments, the first surface 23 of the lens structure 22 may be substantially flat.

The film 10 may include a first surface 12 and a second surface 14 opposite to the first surface in the vertical direction, and the first surface 12 of the film 10 may partially contact the first surface 27 of the image sensor chip 20 including the first surface 23 of the lens structure 22. The second surface 14 of the film 10 may contact a surface of the ring 30.

In example embodiments, the second surface 14 of the film 10 may be substantially flat, while the first surface 12 of the film 10 may have an embossing shape. For example, the film 10 may include a plurality of protrusion portions 15, each of which may protrude in the vertical direction, and which may be disposed in the horizontal direction. Thus, in an example embodiment, the first surface 12 of the film 10 not be flat, but may instead include concave portions and convex portions alternately and repeatedly disposed in the horizontal direction.

In an example embodiment, a length in the vertical direction of each of the protrusion portions 15 may be in a range of about 0.2 mm to about 0.3 mm, and a pitch P between the protrusion portions 15 in the horizontal direction may be in a range of about 0.3 mm to about 0.7 mm.

In example embodiments, the film 10 may be an ultraviolet (UV) curing tape. That is, when a UV light is irradiated on the film 10, the adhesion may be weaken so that the film 10 may be separated from an object.

As the first surface 12 of the film 10 of the example embodiment is not flat, the film 10 may not entirely contact the first surface 23 of the lens structure 22, but may instead partially contact the first surface 23 of the lens structure 22. Thus, when the image sensor chip 20 including the lens structure 22 is separated from the film 10, an adhesion area between the image sensor chip 20 and the film 10 may be smaller than if the film were flat, so that the adhesion of the film 10 with respect to the image sensor chip 20 may be relatively small. As a result, in an example embodiment, the image sensor chip 20 may be relatively easily separated from the film 10, without tearing the film 10. Accordingly, other image sensor chips 20 on the film 10 may not be damaged.

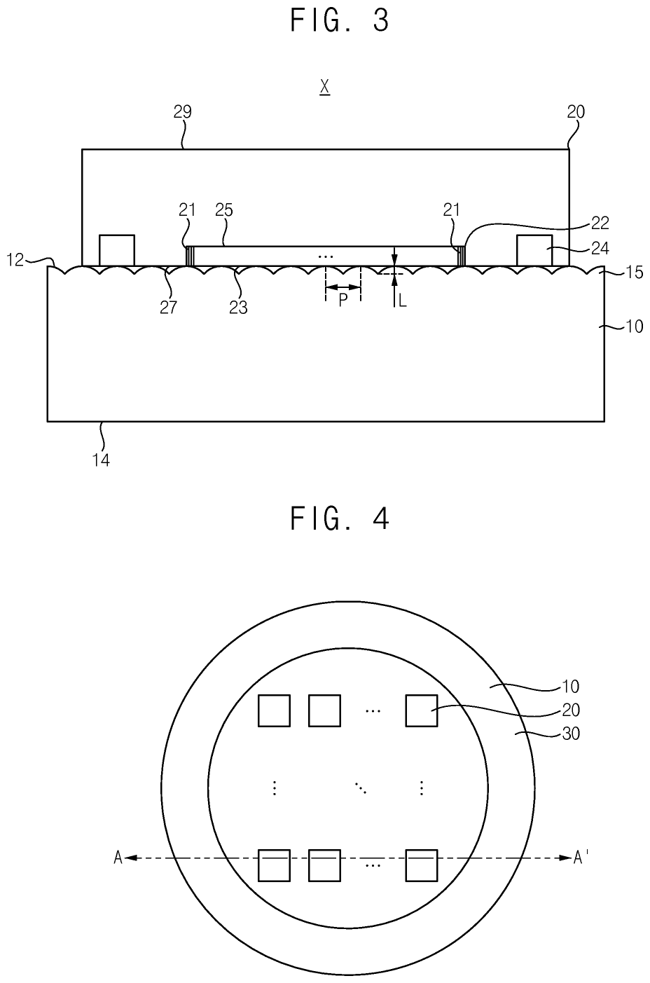

FIG. 4 is a plan view illustrating a film for transferring an image sensor, and FIG. 5 is a cross-sectional view taken along line A-A′ of FIG. 3.

Referring to FIGS. 4 and 5, unlike the film 10 illustrated with reference to FIGS. 1 to 3, instead of the second surface 14 of the film 10, the first surface 12 on which the protrusion portions 15 are formed may contact a surface of the ring 30.

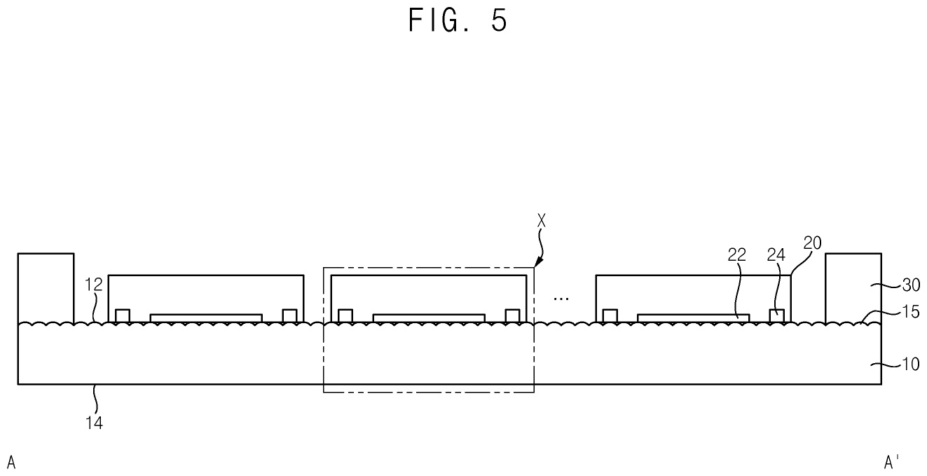

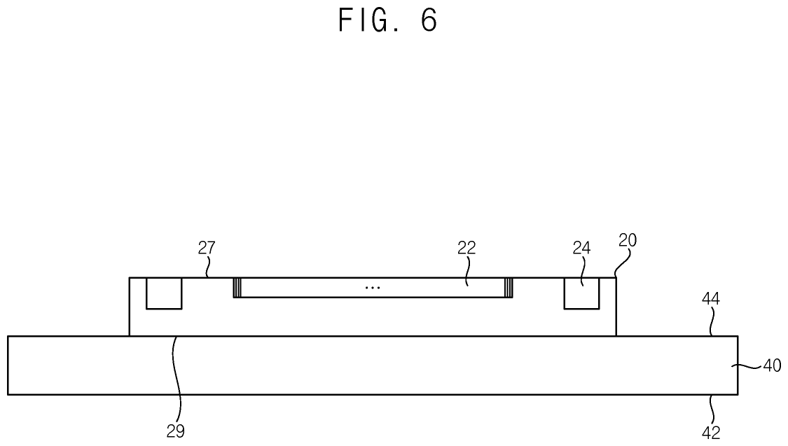

FIGS. 6 to 8 are cross-sectional views illustrating a method of manufacturing an image sensor package in accordance with example embodiments.

Referring to FIG. 6, the image sensor chip 20 may be separated from the film 10 shown in FIGS. 1 to 3, and may be mounted on a package substrate 40.

In example embodiments, UV light may be irradiated onto the film 10 to weaken the adhesion of the film 10, and the image sensor chip 20 may be picked up from the film 10 so as to be separated. The first surface 12 of the film 10 contacting the first surface 27 of the image sensor chip 20 may include the protrusion portions 15 so that a contact area between the first surface 27 of the image sensor chip 20 and the film 10 may be small.

Thus, in an example embodiment, the adhesion of the film 10 with respect to the image sensor chip 20 may be small so that the image sensor chip 20 may be easily separated from the film 10, and the film 10 may not be torn when the image sensor chip 20 is separated. Accordingly, other image sensor chips 20 on the film 10 may not be damaged.

The package substrate 40 may include a first surface 42 and a second surface 44 opposite to the first surface 42 in the vertical direction, and the image sensor chip 20 may be mounted onto the package substrate 40 so that the second surface 29 of the image sensor chip 20 may contact the second surface 44 of the package substrate 40.

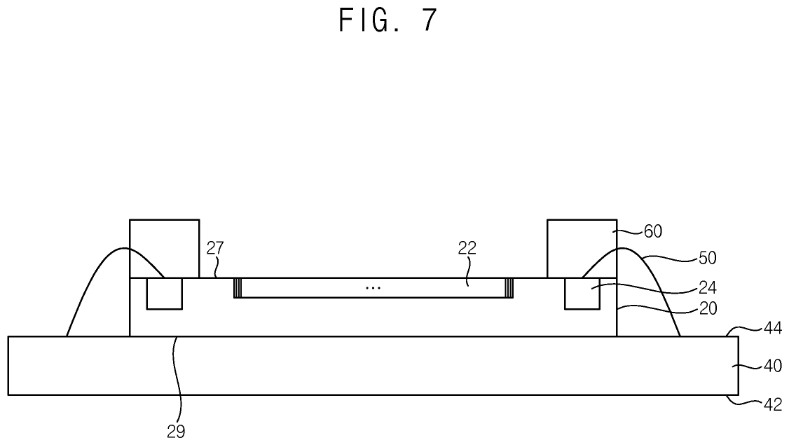

Referring to FIG. 7, in an example embodiment there may be a conductive wire 50 for electrically connecting the image sensor chip 20 and the package substrate 40.

In an example embodiment, the conductive wire 50 may contact the conductive pad 24 of the image sensor chip 20 and a conductive pattern adjacent to the second surface 44 of the package substrate 40, so that the conductive pad 24 and the conductive pattern may be electrically connected thereto.

An adhesion layer 60 may be formed on an edge portion of the first surface 27 of the image sensor chip 20. In example embodiments, the adhesion layer 60 may cover a portion of the conductive wire 50 on the image sensor chip 20.

In an example embodiment, the adhesion layer 60 may have a shape or function of a dam. The adhesion layer 60 may include, e.g., epoxy resin, UV resin, polyurethane resin, silicon resin, silica filler, etc.

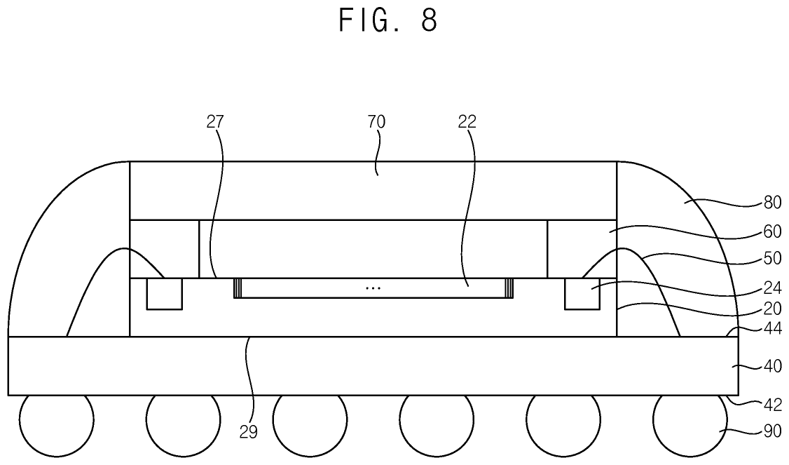

Referring to FIG. 8, a transparent plate 70 may be formed on the adhesion layer 60.

The transparent plate 70 may include a transparent material. Thus, an incident light may penetrate through the transparent plate 70 to the lens structure 22 of the image sensor chip 20. The transparent plate 70 may include, e.g., glass, aluminum nitride, etc.

A sealing element 80 may be disposed on or cover sidewalls of the transparent plate 70, the adhesion layer 60 and the image sensor chip 20, and may also be disposed on or cover a portion of the conductive wire 50 at an outside of the transparent plate 70, the adhesion layer 60 and the image sensor chip 20. The sealing element 80 may include, e.g., epoxy mold compound (EMC).

A connection element 90 may be formed on the first surface 42 of the package substrate 40. In an example embodiment the connection element 90 may be formed by a plating process. Alternatively, the connection element 90 may be formed by, e.g., a screen printing process, a deposition process, etc.

The image sensor package may be manufactured by the above processes.

As illustrated above, the image sensor chip 20 may be separated from the film 10 for transferring an image sensor on the ring 30, and may be mounted onto the package substrate 40. As the first surface 12 of the film 10 contacting the flat first surface 27 of the image sensor chip 20 including the lens structure 22 is not flat, the film 10 and the image sensor chip 20 may partially contact each other.

Thus, in an example embodiment, when the image sensor chip 20 is separated from the film 10, a contact area between the image sensor chip 20 and the film 10 may be small so that the adhesion between the image sensor chip 20 and the film 10 may be small. As a result, the image sensor chip 20 may be easily separated from the film 10 without tearing the film 10. Accordingly, in an example embodiment, other image sensor chips 20 disposed on the film 10 may not be damaged.

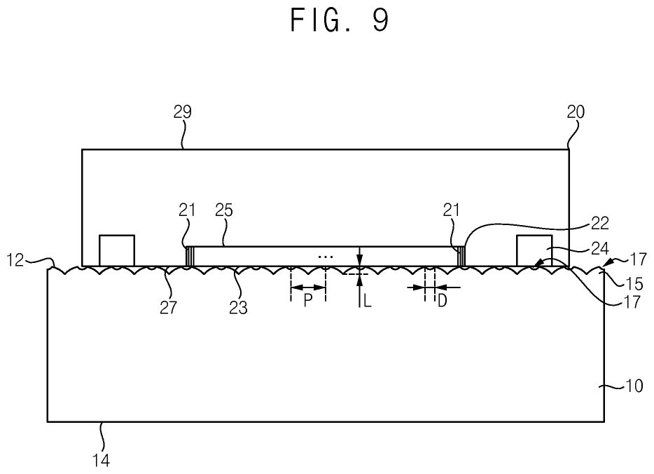

FIG. 9 is a cross-sectional view illustrating a film for transferring an image sensor in accordance with example embodiments, which may correspond to FIG. 3.

The film may be substantially the same as or similar to that of FIGS. 1 to 3, except that the protrusion portion 15 of the film 10 includes a recess 17 thereon.

Referring to FIG. 9, the recess 17 may be formed on the protrusion portion 15 of the film 10.

In an example embodiment, a length in the vertical direction of each of the protrusion portions 15 may be in a range of about 0.2 mm to about 0.3 mm, a pitch P between the protrusion portions 15 in the horizontal direction may be in a range of about 0.3 mm to about 0.7 mm, and a diameter of the recess 17 in the horizontal direction may be in a range of about 0.1 mm to about 0.2 mm.

Thus, the contact area of the portion of the first surface 12 of the film 10 contacting the first surface 27 of the image sensor chip 20 may decrease.

Accordingly, in an example embodiment, when the image sensor chip 20 is separated from the film 10, the adhesion of the film 10 with respect to the image sensor chip 20 may much more decrease, and thus the image sensor chip 20 may be effectively separated from the film 10 without tearing the film 10.

While aspects of example embodiments have been particularly shown and described, it will be understood that various changes in form and details may be made therein without departing from the spirit and scope of the following claims.

What is claimed is:

1. A film for transferring an image sensor, the film comprising:
a first surface and a second surface opposite the first surface in a vertical direction;
protrusion portions disposed in a horizontal direction on the first surface; and
a recess on each of the protrusion portions.

2. The film for transferring an image sensor of claim 1, wherein a length in the vertical direction of each of the protrusion portions is in a range of about 0.2 mm to about 0.3 mm.

3. The film for transferring an image sensor of claim 1, wherein a pitch in the horizontal direction between the protrusion portions is in a range of about 0.3 mm to about 0.7 mm.

4. The film for transferring an image sensor of claim 1, wherein a diameter in the horizontal direction of the recess is in a range of about 0.1 mm to about 0.2 mm.

5. A method of manufacturing an image sensor package, the method comprising:
separating an image sensor chip attached to a first surface of a film for transferring an image sensor from the film, the film being attached to a ring, the film comprising the first surface and a second surface opposite to the first surface in a vertical direction, and the film comprising protrusion portions disposed in a horizontal direction on the first surface of the film;
mounting the image sensor chip onto a package substrate;
forming an adhesion layer on the image sensor chip;
placing a transparent plate onto the adhesion layer; and
forming a sealing element on the package substrate and sidewalls of the image sensor chip, the adhesion layer and the transparent plate.

6. The method of manufacturing an image sensor package of claim 5, wherein the image sensor chip comprises first and second surfaces opposite to each other in the vertical direction, and the first surface of the image sensor chip is flat,
wherein the first surface of the image sensor chip contacts the first surface of the film.

7. The method of manufacturing an image sensor package of claim 6, wherein the image sensor chip comprises a lens structure, and
wherein a surface of the lens structure is a portion of the first surface of the image sensor chip.

8. The method of manufacturing an image sensor package of claim 7, wherein the lens structure comprises a plurality of nano prisms disposed in the horizontal direction.

9. The method of manufacturing an image sensor package of claim 5, wherein the second surface of the film is flat, and
wherein the ring contacts the second surface of the film.

10. The method of manufacturing an image sensor package of claim 5, wherein the ring contacts the first surface of the film.

11. The method of manufacturing an image sensor package of claim 5, wherein the image sensor chip is one of a plurality of image sensor chips on the first surface of the film.

12. The method of manufacturing an image sensor package of claim 5, further comprising placing a conductive wire for electrically connecting the image sensor chip and the package substrate to each other.

13. The method of manufacturing an image sensor package of claim 5, wherein a length in the vertical direction of each of the protrusion portions is in a range of about 0.2 mm to about 0.3 mm.

14. The method of manufacturing an image sensor package of claim 5, wherein a pitch in the horizontal direction between the protrusion portions is in a range of about 0.3 mm to about 0.7 mm.

15. The method of manufacturing an image sensor package of claim 5, wherein the film comprises a recess on each of the protrusion portions.

16. A method of manufacturing an image sensor package, the method comprising:
separating an image sensor chip attached to a first surface of a film for transferring an image sensor from the film, the film being attached to a ring, the film comprising the first surface and a second surface opposite to the first surface in a vertical direction, the film comprising protrusion portions disposed in a horizontal direction on the first surface of the film, and the film comprising a recess on each of the protrusion portions;
mounting the image sensor chip onto a package substrate;
placing a conductive wire configured to electrically connect the image sensor chip to the package substrate;
forming an adhesion layer on the image sensor chip;
placing a transparent plate onto the adhesion layer; and
forming a sealing element on the package substrate and sidewalls of the image sensor chip, the adhesion layer and the transparent plate.

17. The method of manufacturing an image sensor package of claim 16, wherein the image sensor chip comprises a lens structure, and
wherein a surface of the lens structure contacts the first surface of the film.

18. The method of manufacturing an image sensor package of claim 17, wherein the lens structure comprises a plurality of nano prisms disposed in the horizontal direction, and
wherein the surface of the lens structure is flat.

19. The method of manufacturing an image sensor package of claim 16, wherein the image sensor chip is one of a plurality of image sensor chips on the first surface of the film.

20. The method of manufacturing an image sensor package of claim 16, wherein:
a length in the vertical direction of each of the protrusion portions is in a range of about 0.2 mm to about 0.3 mm,
a pitch in the horizontal direction between the protrusion portions is in a range of about 0.3 mm to about 0.7 mm, and
a diameter in the horizontal direction of the recess is in a range of about 0.1 mm to about 0.2 mm.
